(19) United States
(12) Patent Application Publication
(10) Pub. No.: US 2025/0056931 A1
(43) Pub. Date: Feb. 13, 2025

(54) LIGHT EMITTING DIODE ELEMENT AND MANUFACTURING METHOD THEREOF AND LIGHT EMITTING APPARATUS

(71) Applicant: Quanzhou sanan semiconductor technology Co., Ltd., Fujian (CN)

(72) Inventors: Pengjie HU, Fujian (CN); Weifan KE, Fujian (CN); Liping ZHOU, Fujian (CN); Shengnan LIU, Fujian (CN); Jiayu LIU, Fujian (CN)

(73) Assignee: Quanzhou sanan semiconductor technology Co., Ltd., Fujian (CN)

(21) Appl. No.: 18/795,096

(22) Filed: Aug. 5, 2024

(30) Foreign Application Priority Data
Aug. 7, 2023 (CN) 202310985228.X

(51) Int. Cl. H01L 33/46; H01L 25/075; H01L 33/00; H01L 33/30

(52) U.S. Cl. CPC H01L 33/46; H01L 25/0753; H01L 33/0093; H01L 33/30; H01L 2933/0025

(57) ABSTRACT

Disclosed are a light emitting diode element, a manufacturing method thereof, and a light emitting apparatus. In the light emitting diode element, a surface of a first bond layer formed on an epitaxial structure is a smooth surface without height difference. Further, a surface roughness thereof may be less than 10 nm. Therefore, when the substrate and epitaxial structure are bonded, the two bond layers are plane-to-plane bonded, and no defect such as voids occurs to ensure the bonding strength. Thereby, the bonding stability between the substrate and the epitaxial structure is ensured, and the yield of the device is improved. At the same time, there is no similar defect such as voids, which facilitates to reduce the voltage of the device and improve the photoelectric efficiency of the device.

### CROSS-REFERENCE TO RELATED APPLICATION

This application claims the priority benefit of China application serial no. 202310985228.X, filed on Aug. 7, 2023. The entirety of the above-mentioned patent application is hereby incorporated by reference herein and made a part of this specification.

### BACKGROUND

### Technical Field

The disclosure relates to a technical field of semiconductor devices and apparatuses, and in particular to a light emitting diode element and a manufacturing method thereof and a light emitting apparatus.

### Description of Related Art

Compound semiconductors composed of III-V elements have been widely used in many application fields today due to their excellent optoelectronic properties. For example, materials such as gallium phosphide (GaP), gallium arsenide (GaAs), or gallium nitride (GaN) may be used in different fields such as integrated circuits, light emitting diodes, laser diodes, and light detection. Existing LED structures usually include an epitaxial structure which may radiate light. In order to increase the brightness of the product, a mirror system is formed on the epitaxial structure to reflect the light radiated by an epitaxial layer in the required direction. When the aforementioned mirror system is formed, voids are usually formed on the epitaxial structure configured to provide electricity connection.

For the light emitting diode of the vertical structure, a bonding process is usually adopted to bond the epitaxial structure to a permanent substrate. For example, Au—Au bonding or Au—In bonding is usually adopted. When a bond layer is deposited, the aforementioned void structure extends into the bond layer, so that the bond layer also forms a void-like recess. Therefore, when Au—Au bonding or Au—In bonding is performed, void issues occur. The voids in the Au—Au bonding affects the bonding stability and easily causes separation of the epitaxial layer from the substrate, which results in a loss in the yield of the light emitting diode. In addition, the presence of voids affects the expansion of current, which causes the voltage of the device to be too high and results in reduced efficiency of the device. Au—In bonding is expensive in costs and has lower production efficiency.

### SUMMARY

In view of the aforementioned defects of light emitting diodes in the prior art, the disclosure provides a light emitting diode element and a manufacturing method thereof and a light emitting apparatus to solve one or multiple of the aforementioned issues.

An embodiment of the disclosure provides a light emitting diode element. The light emitting diode element at least includes an epitaxial structure, a reflection structure, a first bond layer, and a substrate. The epitaxial structure at least includes a first semiconductor layer structure, an active layer, and a second semiconductor layer structure stacked in sequence. The reflection structure is formed on a side of the second semiconductor layer structure away from the active layer. Vias are formed in the reflection structure. The vias are surrounded by a flat zone. The first bond layer is formed on a side of the reflection structure away from the second semiconductor layer structure, fills the vias, and covers the flat zone. The first bond layer has a first surface and a second surface. The first surface is a side close to the reflection structure, and the second surface is a side away from the reflection structure. The substrate is formed on the second surface of the first bond layer. In a stacking direction of the epitaxial structure, the second surface of the first bond layer and a bottom of the vias have a first distance therebetween, the second surface and a top of the flat zone have a second distance therebetween, the first distance is greater than the second distance, and a difference between the first distance and the second distance is a height of the flat zone.

According to another embodiment of the disclosure, a manufacturing method of a light emitting diode element. The method includes the following steps. A growth substrate is provided. A first semiconductor layer structure, an active layer, and a second semiconductor layer structure sequentially grow on the growth substrate to form an epitaxial structure. A dielectric structure is formed on the second semiconductor layer structure. The dielectric structure is etched to form vias in the dielectric structure. The unetched portion is a flat zone. A metal layer is formed on a side of the dielectric structure away from the second semiconductor layer structure. The metal layer fills the vias and covers the flat zone. The metal layer has a first surface and a second surface. The first surface is a side close to the dielectric structure. The second surface is a side away from the dielectric structure. The second surface of the metal layer is polished, so that, in a stacking direction of the epitaxial structure, the second surface and a bottom of the vias have a first distance therebetween, and the second surface and a top of the flat zone have a second distance therebetween. The first distance is greater than the second distance, and a difference between the first distance and the second distance is a height of the flat zone. A first bond layer is formed on the metal layer. A substrate is bonded. The substrate is bonded on a surface of the first bond layer.

According to another embodiment of the disclosure, a manufacturing method of a light emitting diode element is provided. The method includes the following steps. A growth substrate is provided. A first semiconductor layer structure, an active layer, and a second semiconductor layer structure sequentially grow on the growth substrate to form an epitaxial structure. A dielectric structure is formed on the second semiconductor layer structure. The dielectric structure is etched to form vias in the dielectric structure. The unetched portion is a flat zone. A metal layer is formed on a side of the dielectric structure away from the second semiconductor layer structure. The metal layer fills the vias and covers the flat zone. The metal layer has a third surface and a fourth surface. The third surface is a side close to the dielectric structure. The fourth surface is a side away from the dielectric structure. The fourth surface of the metal layer is polished, so that the fourth surface and a bottom of the vias have a third distance therebetween, and the fourth surface and a top of the flat zone have a fourth distance therebetween, the third distance is greater than the fourth distance, and a difference between the third distance and the fourth distance is a height of the flat zone. A first bond layer is formed on the metal layer. A substrate is bonded. The substrate is bonded on a surface of the first bond layer.

According to another embodiment of the disclosure, a light emitting apparatus is provided. The light emitting apparatus includes a circuit board and a light emitting element disposed on the circuit board. The light emitting element includes the light emitting diode element provided by the disclosure.

As described above, the light emitting diode element and the manufacturing method thereof and the light emitting apparatus of the disclosure have the following beneficial effects. In the light emitting diode element of the disclosure, the surface of the first bond layer formed on the epitaxial structure is the flat surface without any height difference, and further, the surface roughness thereof may be less than 10 nm. Therefore, when the substrate and epitaxial structure are bonded, the two bond layers are plane-to-plane bonded, and no defect such as voids occurs to ensure the bonding strength. Thereby, the structural stability between the substrate and epitaxial structure is ensured, and the yield of the device is improved. Further, there is no defect such as voids between the two bond layers, which facilitates to reduce the voltage of the device and improve the photoelectric efficiency of the device.

### BRIEF DESCRIPTION OF THE DRAWINGS

FIG. 1 is a schematic diagram of a structure of a light emitting diode of a vertical structure in the prior art.

FIG. 2A and FIG. 2B are scanning electron microscope images of the structure shown in FIG. 1.

FIG. 3 is a schematic diagram of a structure of a light emitting diode element according to the first embodiment of the disclosure.

FIG. 4 is a flowchart of a manufacturing process of the light emitting diode element shown in FIG. 3.

FIG. 5 is a schematic diagram of formation of an epitaxial structure and a transparent conductive layer on a growth substrate.

FIG. 6 is a schematic diagram of formation of a reflection structure on the structure shown in FIG. 5.

FIG. 7 is a schematic diagram of formation of a first bond layer on the structure shown in FIG. 6.

FIG. 8 is a schematic diagram of the structure shown in FIG. 7 after polishing the first bond layer.

FIG. 9 is a schematic diagram of a structure of formation of a second bond layer on a substrate.

FIG. 10 is a schematic diagram of a structure of a light emitting diode element according to the second embodiment of the disclosure.

FIG. 11 is a flowchart of a manufacturing process of the light emitting diode element shown in FIG. 10.

FIG. 12 is a schematic diagram of a structure shown in FIG. 6 after grinding and polishing the reflection structure.

FIG. 13 is a schematic diagram of a structure of formation of a first bond layer on the structure shown in FIG. 12.

FIG. 14 is a schematic diagram of a light emitting apparatus according to the third embodiment of the disclosure.

### DESCRIPTION OF THE EMBODIMENTS

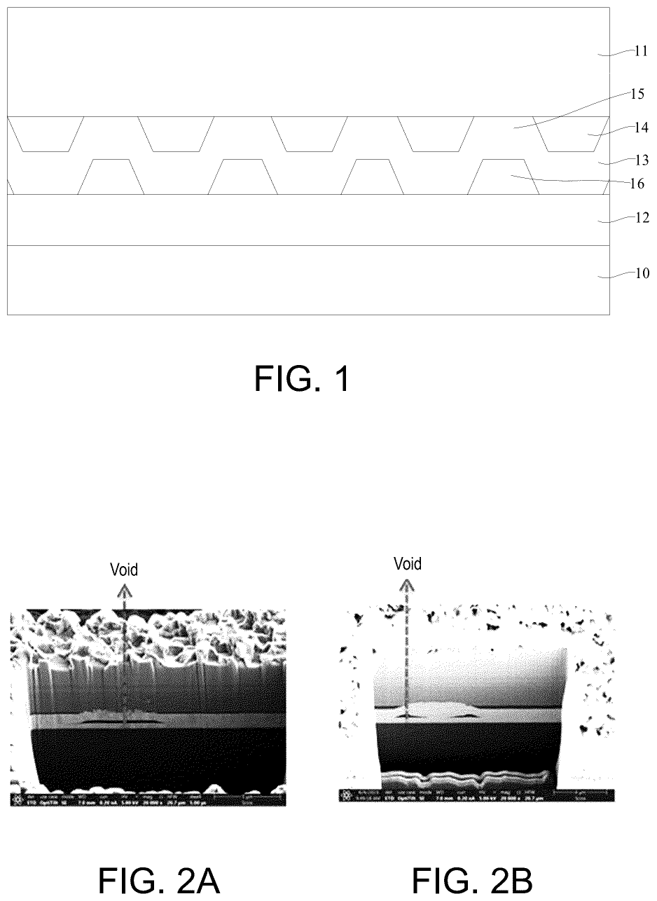

As shown in FIG. 1, in the prior art, a light emitting diode of a vertical structure includes a substrate 10 and an epitaxial layer 11. In a direction from the substrate 10 to the epitaxial layer 11, a second bond layer 12, a first bond layer 13, and a reflection structure 14 are formed between the substrate 10 and the epitaxial layer 11. Vias 15 are usually formed in the reflection structure 14. The presence of the vias 15 makes the first bond layer 13 formed on the reflection structure 14 form an uneven surface structure. When the first bond layer 13 is bonded to the second bond layer 12, defects such as voids 16 are easily formed on a bonding interface. As shown in FIG. 2A and FIG. 2B, obvious voids are formed on the bonding interface. Even if Au—Au bonding is adopted, metal Au may properly fill spaces in a bonding process, however, defects such as voids still inevitably occur. On the one hand, the presence of voids reduces the bonding strength and is not conducive for the stability of the device. On the other hand, the presence of voids also affects the current expansion of the device and the electrical performance of the device.

### Embodiment 1

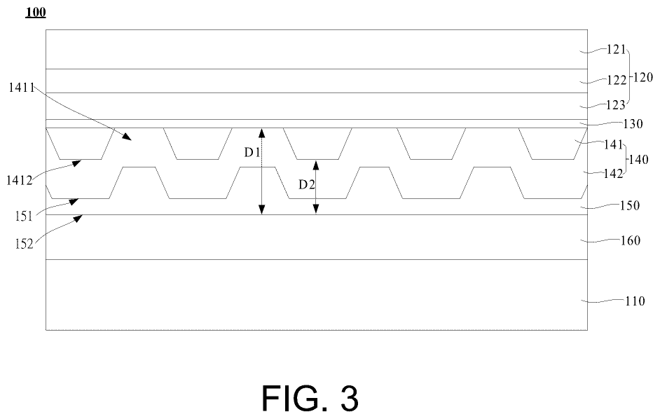

In view of the defects in the prior art such as the presence of voids between bond layers leading to poor bonding firmness, this embodiment provides a light emitting diode element 100. As shown in FIG. 3, a light emitting diode element 100 at least includes an epitaxial structure 120, a reflection structure 140, a first bond layer 150, and a substrate 110. The epitaxial structure 120 at least includes a first semiconductor layer structure 121, an active layer 122, and a second semiconductor layer structure 123 stacked in sequence. The epitaxial structure 120 may be any epitaxial structure which may radiate light under the action of voltage. In this embodiment, the epitaxial structure 120 is preferably an AlGaInP epitaxial structure.

The first semiconductor layer structure 121 may be an N-type layer. Correspondingly, the second semiconductor layer structure 123 may be a P-type layer, and vice versa is also feasible. In this embodiment, the first semiconductor layer structure 121 is an N-type layer, and the second semiconductor layer structure 123 is a P-type layer.

In an optional embodiment, the first semiconductor layer structure 121 is an N-type AlInP layer configured to provide electrons. The N-type AlInP layer is doped with an n-type dopant to provide electrons. The n-type dopant may be, for example, Si, Ge, Sn, Se, Te, etc. In this embodiment, the n-type dopant is preferably Si, and the doping concentration of Si is between 1×10¹⁸ Atoms/cm³ and 2×10¹⁸ Atoms/cm³ to provide electrons for radiative recombination. The second semiconductor layer structure 123 is a P-type AlInP layer which is doped with a p-type dopant to provide holes. The p-type dopant may be Mg, Zn, Ca, Sr, C, Ba, etc. In this embodiment, the p-type dopant is preferably Mg or C.

Referring to FIG. 3, the reflection structure 140 includes a dielectric structure 141 formed on the second semiconductor layer structure 123 and a metal layer 142 formed on a side of the dielectric structure 141 away from the second semiconductor layer structure 123. The aforementioned dielectric structure 141 is an insulating reflection layer, for example, SiNx, SiO₂, TiO₂, or a DBR structure formed by SiO₂ and TiO₂ alternately stacked. The metal layer 142 may be an alloy of one or multiple of Ag, Al, Cu, Sn, Au, etc. In this embodiment, the dielectric structure 141 is the DBR structure, and the metal layer 142 is an Ag mirror, which forms a total reflection mirror having an ODR structure. As shown in FIG. 3, a transparent conductive layer 130 is formed between the reflection structure 140 and the second semiconductor layer structure 123. The transparent conductive layer 130 may be a transparent metal oxide layer, such as ITO and IZO.

Referring to FIG. 3, vias 1411 are formed in the dielectric structure 141 of the reflection structure 140. The vias 1411 penetrate the dielectric structure 141 and exposes the transparent conductive layer 130. An area around the vias 1411 is formed as a flat zone 1412. The metal layer 142 is formed on the dielectric structure 141 and fills the vias 1411 to form on the transparent conductive layer 130 and form a good contact with the transparent conductive layer 130, which facilitates the subsequent supply of voltage to the second semiconductor layer structure 123 through the metal layer 142 and the transparent conductive layer 130. Since the dielectric structure 141 has the vias 1411, the metal layer 142 formed thereon also establishes an uneven surface structure.

The first bond layer 150 is formed on a side of the metal layer 142 away from the dielectric structure 141. Optionally, the first bond layer 150 is a metal material layer, such as Cu, Al, Sn, Au, Ag, Pb, Ti, Ni, In, Pt, or W. In this embodiment, the Au layer is taken as an example. As shown in FIG. 3, in this embodiment, a side of the first bond layer 150 close to the metal layer 142 is defined as a first surface 151, and a side away from the metal layer 142 and opposite to the first surface 151 is defined as a second surface 152. Since the first bond layer 150 is formed on the metal layer 142, the first surface 151 close to the metal layer 142 also establishes an uneven surface structure. In this embodiment, the second surface 152 and a bottom of the vias 1411 of the dielectric structure 141 have a first distance D1 therebetween, and the second surface 152 and a top of the flat zone 1412 of the dielectric structures 141 have a second distance D2 therebetween. The first distance D1 is greater than the second distance D2, and a difference between the first distance D1 and the second distance D2 is a height of the flat zone 1412 (a height of the dielectric structure 141). As shown in FIG. 3, the second surface 152 of the first bond layer 150 establishes a flat surface without height difference.

Referring to FIG. 3, a second bond layer 160 is formed on a side of the first bond layer 150 near the second surface 152, and the substrate 110 is bonded to a side of the epitaxial structure 120 by the second bond layer 160 and the first bond layer 150. The second bond layer 160 is also a metal material layer, such as Cu, Al, Sn, Au, Ag, Pb, Ti, Ni, In, Pt, or W. In this embodiment, the Au layer is also taken as an example. As described above, the second surface 152 of the first bond layer 150 is a flat surface. Similarly, the second bond layer 160 is also a flat surface. Therefore, when the two are bonded, the bond is between flat surfaces without forming voids, the bonding strength is improved, which improves the reliability of the light emitting diode element 100.

The substrate 110 may be an insulating substrate, a semiconductor substrate, a metal substrate, etc. In this embodiment, the substrate 110 is a silicon (Si) substrate, a germanium (Ge) substrate, a silicon carbide (SiC) substrate, a gallium nitride (GaN) substrate, an aluminum nitride (AlN) substrate, a gallium phosphide (GaP) substrate, or a gallium arsenide (GaAs) substrate, etc.

Although not specifically illustrated, it should be understood that the light-emitting diode element 100 of this embodiment further includes an electrode structure. The electrode structure includes a first electrode formed on the first semiconductor layer structure 121 and electrically connected to the first semiconductor layer structure 121, and a second electrode formed on a back side of the substrate 110 and electrically connected to the second semiconductor layer structure 123. The second electrode may be a metal layer on the back side of the substrate 110.

In an optional embodiment, the first bond layer 150 together with the metal layer 142 may be a same structural layer formed of the same metal (for example, a same structural layer formed of Au).

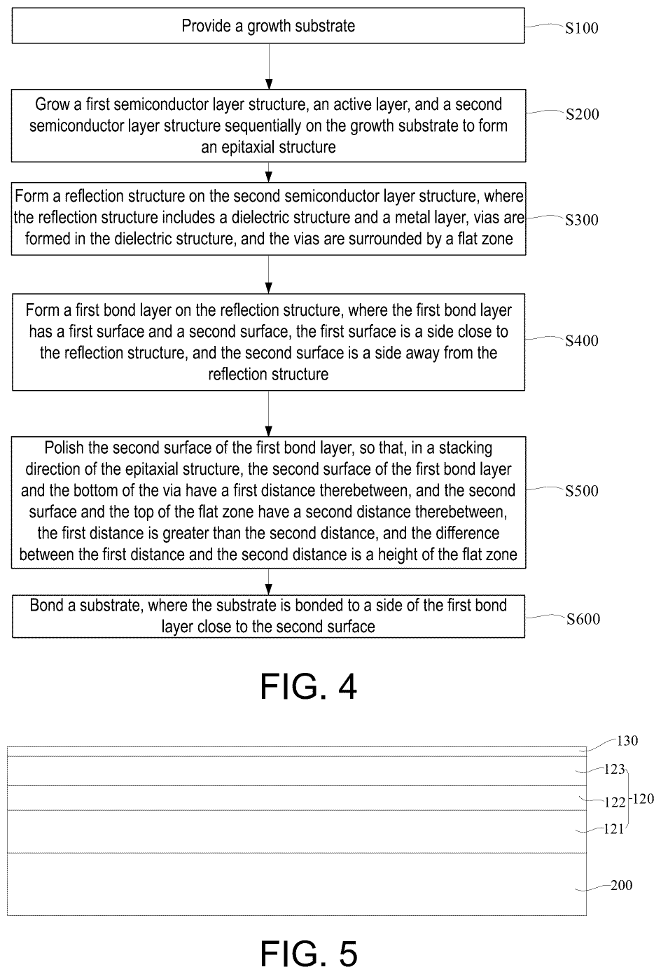

This embodiment further provides a manufacturing method of the light emitting diode element 100. As shown in FIG. 4, the method includes the following steps. In step S100, a growth substrate is provided. In step S200, a first semiconductor layer structure, an active layer, and a second semiconductor layer structure sequentially grow on the growth substrate to form an epitaxial structure.

Referring to FIG. 5, a growth substrate 200 is provided first. The growth substrate 200 may be any substrate suitable for epitaxy, such as a Si substrate, a SiC substrate, a sapphire substrate, and a GaAs substrate. In this embodiment, the GaAs substrate is adopted.

Epitaxial growth is performed on a front side of the GaAs substrate to sequentially grow a first semiconductor layer structure 121, an active layer 122 and a second semiconductor layer structure 123. In this embodiment, the first semiconductor layer structure 121 is an N-type semiconductor layer, the n-type dopant is preferably Si, and the doping concentration is between 1×10¹⁸ Atoms/cm³ and 2×10¹⁸ Atoms/cm³ to provide electrons for radiative recombination. The second semiconductor layer structure 123 is a P-type semiconductor layer, and the p-type dopant may be Mg, Zn, Ca, Sr, C, Ba, etc.

In step S300, a reflection structure on the second semiconductor layer structure is formed. The reflection structure includes a dielectric structure and a metal layer. Vias are formed in the dielectric structure. The vias are surrounded by a flat zone.

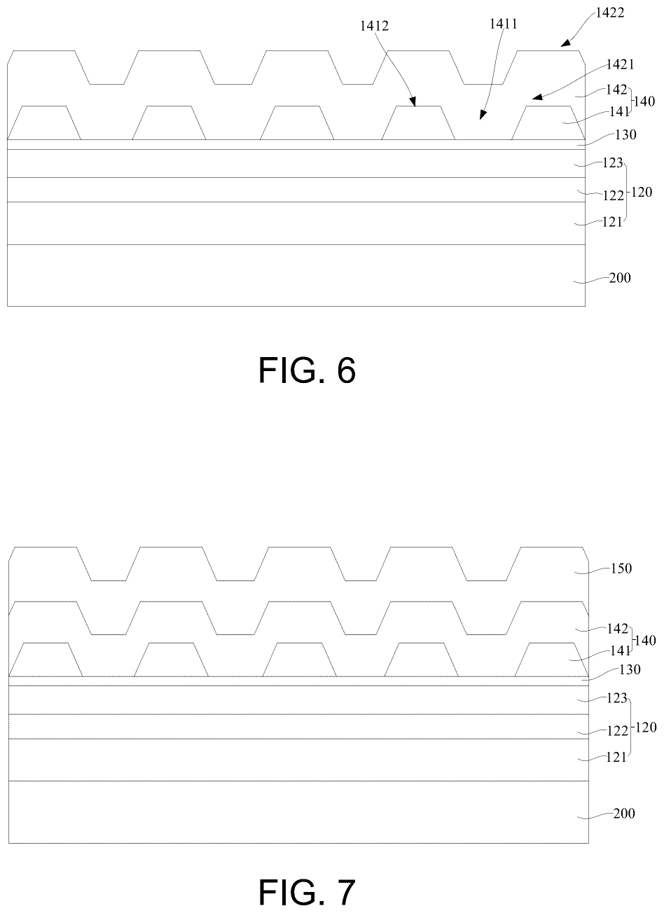

Before the reflection structure 140 is formed, as shown in FIG. 5, the transparent conductive layer 130 is first formed on the second semiconductor layer structure 123. The transparent conductive layer 130 covers the second semiconductor layer structure 123 and forms an ohmic contact therewith. The transparent conductive layer 130 is a transparent metal oxide layer, such as ITO and IZO. Afterwards, as shown in FIG. 6, the reflection structure 140 is formed on the second semiconductor layer structure 123, that is, on the transparent conductive layer 130. Optionally, an insulating reflection layer is first deposited on the transparent conductive layer 130 to form the dielectric structure 141. The insulating reflection layer may be SiNx, SiO₂, TiO₂, or a DBR structure formed by SiO₂ and TiO₂ alternately stacked. In this embodiment, the DBR structure is formed on the transparent conductive layer 130. After the dielectric structure 141 is formed, etching the dielectric structure 141 is further included to form the vias 1411 penetrating the dielectric structure 141 and exposing the transparent conductive layer 130, and the unetched portion is still retained as the flat zone 1412. The vias 1411 may be multiple and may be distributed in the dielectric structure 141 in any manner.

Referring to FIG. 6, the metal layer 142 is then formed on the dielectric structure 141, that is, on the DBR structure. The metal layer 142 covers the flat zone 1412 and fills the vias 1411. The metal layer 142 may be an alloy of one or multiple of Ag, Al, Cu, Sn, Au, etc. In this embodiment, an Ag mirror layer is preferably adopted, and the Ag mirror layer and the DBR structure form the total reflection mirror having the ODR structure. Since the dielectric structure 141 includes the vias 1411 and the flat zone 1412, the metal layer 142 formed thereon is concave in the area corresponding to the vias 1411 and is flat in the flat zone 1412, so that the entire reflection structure 140 establishes an uneven surface structure as shown in FIG. 6.

In step S400, a first bond layer is formed on the reflection structure. The first bond layer has a first surface and a second surface. The first surface is a side close to the reflection structure, and the second surface is a side away from the reflection structure.

As shown in FIG. 7, the first bond layer 150 is formed on the metal layer 142 of the reflection structure 140. The first bond layer 150 is a metal material layer, such as Cu, Al, Sn, Au, Ag, Pb, Ti, Ni, In, Pt, or W. In this embodiment, the Au layer is also taken as an example. In this embodiment, the side of the first bond layer 150 close to the metal layer 142 is defined as the first surface 151, and the side away from the metal layer 142 is defined as the second surface 152. The Au layer of a certain thickness is deposited on the metal layer 142. Due to the conformal feature, the formed first bond layer 150 also has an uneven surface structure, that is, a recess is formed at a position corresponding to the vias 1411, and a flat structure is correspondingly formed in the area corresponding to the flat zone 1412. Both the first surface 151 and the second surface 152 have the aforementioned structural features.

In an optional embodiment, the first bond layer 150 and the metal layer 142 may be the same metal material layer, for example, Au layers. In this manner, after the dielectric structure 141 is formed, a metal layer may be deposited on the dielectric structure 141 to serve as the metal layer 142 and the first bond layer 150.

In step S500, the second surface of the first bond layer is polished, so that, in a stacking direction of the epitaxial structure, the second surface of the first bond layer and the bottom of the vias have a first distance, and the second surface of the first bond layer and the top of the flat zone have a second distance. Moreover, the first distance is greater than the second distance, and the difference between the first distance and the second distance is the height of the flat zone.

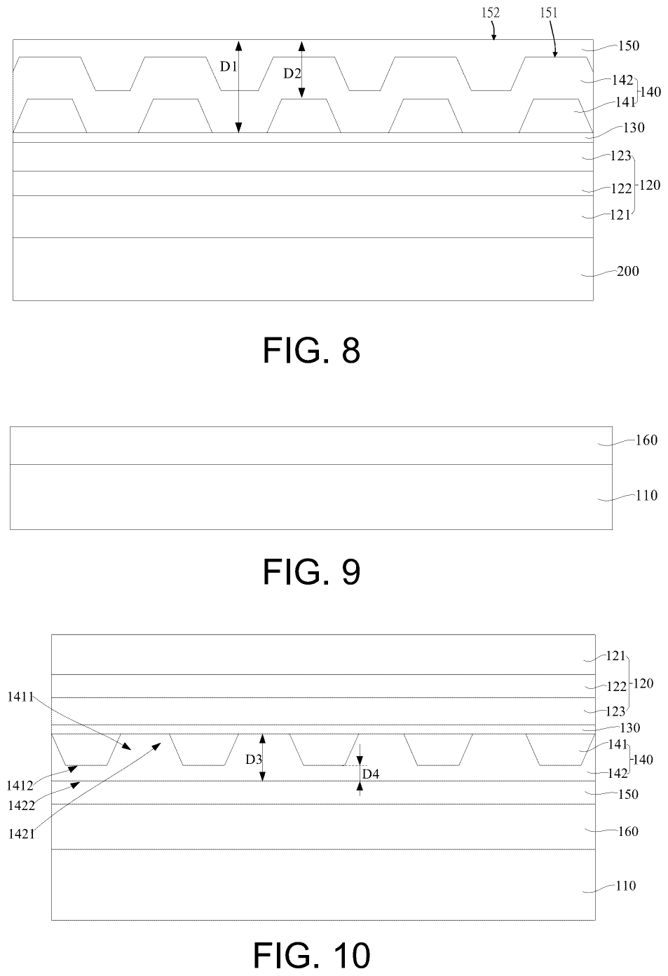

As shown in FIG. 8, on a side of the second surface 152, the first bond layer 150 is ground and polished to form a smooth surface. In this manner, the second surface 152 of the first bond layer 150 and the bottom of the vias 1411 are defined to have the first distance D1 therebetween, and the second surface 152 and the top of the flat zone 1412 are defined to have the second distance D2 therebetween. As can be seen from FIG. 8, the first distance D1 is greater than the second distance D2, and the difference between the first distance D1 and the second distance D2 is the height of the flat zone 1412. It can be seen that the second surface 152 is a flat and smooth surface after the grinding and polishing, and is no longer an uneven surface, which facilitates to completely adhere the second bond layer 160 during subsequent bonding to ensure that defects such as voids do not occur.

In an optional embodiment, the second surface 152 is ground and polished, so that the surface roughness of the second surface 152 is less than or equal to 10 nm. Therefore, the flatness of the second surface 152 may be further improved to ensure that no voids occur during the bonding process.

In step S600, a substrate is bonded. The substrate is bonded to a side of the first bond layer close to the second surface.

As shown in FIG. 9, the second bond layer 160 is formed on a front side of the substrate 110. The substrate may be, for example, a Si substrate 110, a Ge substrate 110, a SiC substrate 110, a GaN substrate 110, an AlN substrate 110, a GaP substrate 110, or a GaAs substrate 110. The second bond layer 160 is also a metal material layer, such as Cu, Al, Sn, Au, Ag, Pb, Ti, Ni, In, Pt, or W. In this embodiment, the Au layer is also taken as an example. Since the front side of the substrate 110 is a flat surface, the second bond layer 160 formed thereon also has a flat surface structure. The structure shown in FIG. 8 is flipped, so that the first bond layer 150 and the second bond layer 160 are bonded. Since the first bond layer 150 has a flat and smooth surface after the grinding and polishing, no void is formed on the bonding interface between the first bond layer 150 and the second bond layer 160 during the bonding process, which improves the bonding stability between the two and improves the stability of the device. Further, since there is no defect such as voids, the current expansion of the light emitting diode is also improved, which improves the electrical performance of the device.

Optionally, a metal layer may be formed on the back side of the substrate 110, and the metal layer may be used as a second electrode for providing voltage to the second semiconductor layer structure 123.

After the substrate 110 is bonded, the structure is further flipped, and then the growth substrate 200 is peeled off to expose the first semiconductor layer structure 121, thereby forming the light emitting diode element 100 shown in FIG. 3. Thereafter, a first electrode is further formed on the first semiconductor layer structure 121. The first electrode is electrically connected to the first semiconductor layer structure 121. Optionally, multiple first electrodes may be formed.

In this embodiment, the first distance and the second distance of the first bond layer satisfy a predetermined relationship, and the second surface of the first bond layer is a flat surface without height difference. Therefore, when bonding with the substrate, the second surface is plane-to-plane bonding, and voids and other similar defects are not formed to ensure the bonding strength. Thereby, the bonding stability between the substrate and the epitaxial structure is ensured, and the yield of the device is improved. Further, there is no defect such as voids, which facilitates to reduce the voltage of the device and improve the photoelectric efficiency of the device.

### Embodiment 2

This embodiment also provides a light emitting diode element. As shown in FIG. 10, the light emitting diode element 100 also at least includes an epitaxial structure 120, a reflection structure 140, a first bond layer 150, and a substrate 110. The epitaxial structure 120 at least includes a first semiconductor layer structure 121, an active layer 122, and a second semiconductor layer structure 123 stacked in sequence. The epitaxial structure 120 may be any epitaxial structure which may radiate light under the action of voltage. In this embodiment, the epitaxial structure 120 is preferably an AlGaInP epitaxial structure.

The same points as those in the first embodiment are not described in detail, but the difference is that: in this embodiment, as shown in FIG. 10, a side of the metal layer 142 of the reflection structure 140 close to the dielectric structure 141 is defined as a third surface 1421, and a side away from the dielectric structure 141 is defined as a fourth surface 1422. The third surface 1421 has a structure which is interlocked with the vias 1411 and the flat zone 1412 of the dielectric structure 141, and the fourth surface 1422 is formed as a smooth surface. The fourth surface 1422 and the bottom of the vias 1411 are defined to have a third distance D3 therebetween, and the fourth surface 1422 and the top of the flat zone 1412 are defined to have a fourth distance D4 therebetween. As shown in FIG. 10, the third distance D3 is greater than the fourth distance D4, and a difference between the third distance D3 and the fourth distance D4 is a height of the flat zone 1412. Since the fourth surface 1422 is a smooth surface, the first bond layer 150 formed thereon also establishes a smooth surface structure. Thus, the bond between the first bond layer 150 and the second bond layer 160 is a flat-surface-to-flat-surface bond without forming voids, the bonding strength is improved, which improves the reliability of light emitting diode element 100.

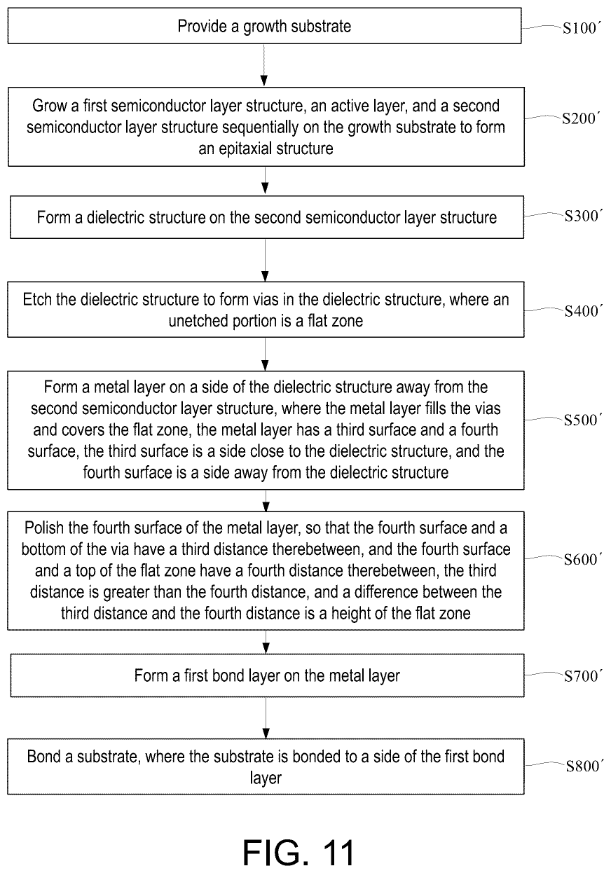

This embodiment also provides a manufacturing method of the light emitting diode element. The flowchart of the manufacturing method is shown in FIG. 11. The step S100′ to the step S400′ correspond to the method described in the first embodiment. The difference lies in that: as shown in FIG. 6, in step S500′, the metal layer 142 is first deposited on the dielectric structure 141, and the side of the metal layer 142 of the reflection structure 140 close to the dielectric structure 141 is defined as the third surface 1421, and the side away from the dielectric structure 141 is defined as the fourth surface 1422. In this manner, the third surface 1421 of the metal layer 142 has a structure which is mutually interlocked with the vias 1411 and the flat zone 1412 of the dielectric structure 141. The fourth surface 1422 forms an uneven surface, that is, a recess is formed at a position corresponding to the vias 1411, and the area corresponding to the flat zone 1412 is also a flat surface.

In step S600′, the fourth surface 1422 of the metal layer 142 is polished, so that the fourth surface 1422 and the bottom of the vias 1411 have the third distance therebetween, and the fourth surface 1422 and the top of the flat zone 1412 have the fourth distance therebetween. Moreover, the third distance is greater than the fourth distance, and the difference between the third distance and the fourth distance is the height of the flat zone 1412.

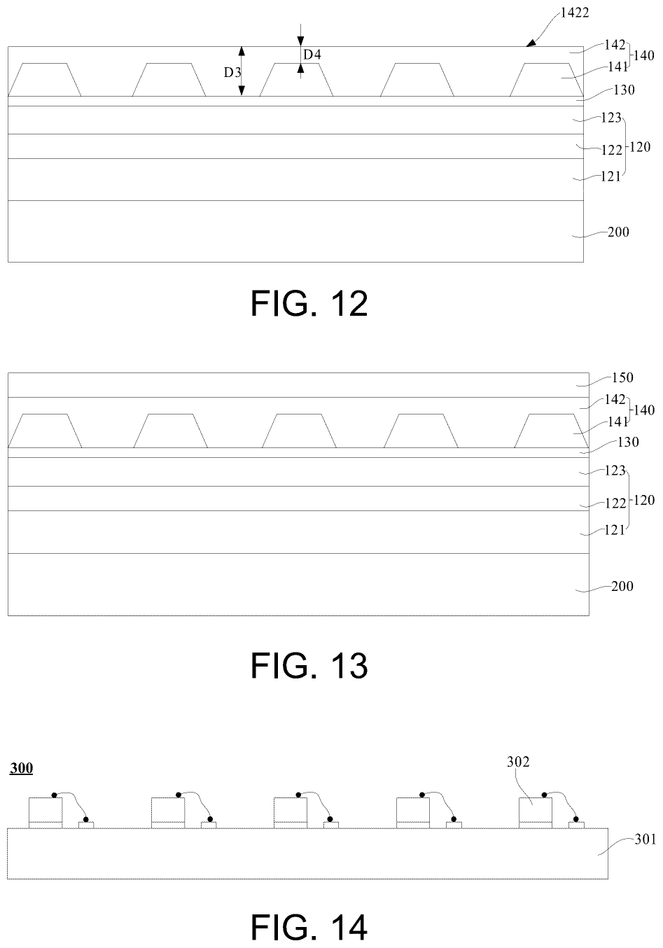

Thereafter, as shown in FIG. 12, the fourth surface 1422 of the metal layer 142 is ground and polished to form a smooth surface. Also as shown in FIG. 12, the fourth surface 1422 and the bottom of vias 1411 are defined to have the third distance D3 therebetween, and the fourth surface 1422 and the top of flat zone 1412 are defined to have the fourth distance D4 therebetween. As can be seen from FIG. 12, the third distance D3 is greater than the fourth distance D4, and the difference between the third distance D3 and the fourth distance D4 is the height of flat zone 1412. Since the fourth surface 1422 is a smooth surface, the first bond layer 150 is formed on the fourth surface 1422 (see step S700′) with reference to FIG. 13. The first bond layer 150 inherits the surface feature of the metal layer 142, so the first bond layer 150 also has a smooth surface structure. Thereafter, the substrate 110 is bonded (see step S800′) in the same manner as described in the first embodiment. This method provides that the bond formed between the first bond layer 150 and the second bond layer 160 is a flat-surface-to-flat-surface bond without voids therebetween, the bonding strength is improved, thereby improving the reliability of the light emitting diode element 100.

### Embodiment 3

This embodiment provides a light emitting device. As shown in FIG. 14, a light emitting device 300 includes a circuit board 301 and a light emitting element 302 disposed on the circuit board 301. The light emitting element 302 may be the light emitting diode element 100 according to the first embodiment and/or the second embodiment of the disclosure. The light emitting device 300 is an LED backlight device or an RGB display device.

What is claimed is:

1. A light emitting diode element, at least comprising:
an epitaxial structure, wherein the epitaxial structure at least comprises a first semiconductor layer structure, an active layer, and a second semiconductor layer structure stacked in sequence;
a reflection structure, wherein the reflection structure is formed on a side of the second semiconductor layer structure away from the active layer, vias are formed in the reflection structure, and the vias are surrounded by a flat zone;
a first bond layer, wherein the first bond layer is formed on a side of the reflection structure away from the second semiconductor layer structure, fills the vias, and covers the flat zone, the first bond layer has a first surface and a second surface, the first surface is a side close to the reflection structure, and the second surface is a side away from the reflection structure; and
a substrate, formed on the second surface of the first bond layer;
wherein, in a stacking direction of the epitaxial structure, the second surface of the first bond layer and a bottom of the vias have a first distance therebetween, the second surface of the first bond layer and a top of the flat zone have a second distance therebetween, the first distance is greater than the second distance, and a difference between the first distance and the second distance is a height of the flat zone.

2. The light emitting diode element according to claim 1, wherein a surface roughness of the second surface of the first bond layer is less than or equal to 10 nm.

3. The light emitting diode element according to claim 1, wherein the first surface of the first bond layer has a structure corresponding to the vias and the flat zone.

4. A light emitting diode element, at least comprising:
an epitaxial structure, wherein the epitaxial structure at least comprises a first semiconductor layer structure, an active layer, and a second semiconductor layer structure stacked in sequence; and
a reflection structure, wherein the reflection structure is formed on a side of the second semiconductor layer structure away from the active layer, vias are formed in the reflection structure, and the vias are surrounded by a flat zone, and the reflection structure comprises:
a dielectric structure, located on the second semiconductor layer structure, wherein the vias are formed in the dielectric structure and penetrates the dielectric structure; and
a metal layer, wherein the metal is formed on a side of the dielectric structure away from the second semiconductor layer structure and fills the vias, the metal layer has a first surface and a second surface, the first surface is a side close to the dielectric structure, and the second surface is a side away from the dielectric structure, the second surface and a bottom of the vias have a first distance therebetween, the second surface and a top of the flat zone have a second distance therebetween, the first distance is greater than the second distance, and a difference between the first distance and the second distance is a height of the flat zone.

5. The light emitting diode element according to claim 4, wherein a surface roughness of the second surface of the metal layer is less than or equal to 10 nm.

6. The light emitting diode element according to claim 4, wherein the first surface of the metal layer has a structure corresponding to the vias and the flat zone.

7. The light emitting diode element according to claim 4, further comprising a second bond layer located between the substrate and the first bond layer, wherein the substrate is bonded to the epitaxial structure by the second bond layer and the first bond layer.

8. The light emitting diode element according to claim 7, further comprising a transparent conductive layer, wherein the transparent conductive layer is formed between the second semiconductor layer structure and the reflection structure, and the vias of the reflection structure expose the transparent conductive layer.

9. A manufacturing method of a light emitting diode element, comprising the following steps:
providing a growth substrate;
growing a first semiconductor layer structure, an active layer, and a second semiconductor layer structure sequentially on the growth substrate to form an epitaxial structure;
forming a reflection structure on the second semiconductor layer structure, wherein the reflection structure comprises a dielectric structure and a metal layer, vias are formed in the dielectric structure, and the vias are surrounded by a flat zone;
forming a first bond layer on the reflection structure, wherein the first bond layer has a first surface and a second surface, the first surface is a side close to the reflection structure, and the second surface is a side away from the reflection structure;
polishing the second surface of the first bond layer, so that, in a stacking direction of the epitaxial structure, the second surface of the first bond layer and a bottom of the vias have a first distance therebetween, and the second surface and a top of the flat zone have a second distance therebetween, the first distance is greater than the second distance, and a difference between the first distance and the second distance is a height of the flat zone; and
bonding a substrate, wherein the substrate is bonded on the second surface of the first bond layer.

10. The manufacturing method of the light emitting diode element according to claim 9, wherein the step of forming the reflection structure on the second semiconductor layer structure further comprises the following steps:
forming a dielectric structure on the second semiconductor layer structure;
etching the dielectric structure to form vias in the dielectric structure, wherein an unetched portion is the flat zone; and
forming a metal layer on a side of the dielectric structure away from the second semiconductor layer structure, wherein the metal layer fills the vias and covers the flat zone, so that the metal layer has a surface structure corresponding to the vias and the flat zone.
